(19) United States
(12) Patent Application Publication
(10) Pub. No.: US 2009/0015523 A1
(43) Pub. Date: Jan. 15, 2009

(54) Organic Electroluminescence display device

(75) Inventors: Noriharu Matsudate, Kujukuri (JP); Takeshi Ookawara, Mobara (JP)

Correspondence Address: REED SMITH LLP;Suite 1400, 3110 Fairview Park Drive, Falls Church, VA, 22042, US

(73) Assignee: Hitachi Displays, Ltd.

(21) Appl. No.: 12/216,798

(22) Filed: Jul. 10, 2008

(30) Foreign Application Priority Data
Jul. 12, 2007 (JP) 2007-182988

(51) Int. Cl. G09G 3/30

(52) U.S. Cl. 345/76; 315/169.3

(57) ABSTRACT

Provided is an organic electroluminescence display device, in which when center deviations in film formation of organic electroluminescence layers in an arrangement direction of a sub-pixel aperture corresponding to a red light, a sub-pixel aperture corresponding to a green light, and a sub-pixel aperture corresponding to a blue light are denoted by LER(X), LEG(X), and LEB(X) and the center deviations in the film formation of the organic electroluminescence layers in a direction perpendicular to the arrangement direction are denoted by LER(Y), LEG(Y), and LEB(Y), any one of the following formulae is satisfied: LEG(X)≦LEB(X); LEG(X)≦LER(X); LEG(Y)≦LEB(Y); and LEG(Y)≦LER(Y).

### CROSS-REFERENCE TO RELATED APPLICATION

The present application claims priority from Japanese application JP 2007-182988 filed on Jul. 12, 2007, the content of which is hereby incorporated by reference into this application.

### BACKGROUND OF THE INVENTION

1. Field of the Invention

The present invention relates to an organic electroluminescence display device, and more particularly, to an organic electroluminescence display device in which chromaticity fluctuation and luminance fluctuation are suppressed by reflecting results of analysis for deviation in film formation of an organic electroluminescence layer.

2. Description of the Related Art

A display device using an organic electroluminescence element (organic light-emitting diode (OLED)) does not require such a backlight as employed in a liquid crystal display device, and hence it is possible to make the display device thinner and lighter. A color reproducibility technique for the organic electroluminescence element follows the additive color mixing theory involving light emission of three primary colors, similarly to a conventional cathode-ray-tube (CRT). Dots (pixels, or sub-pixels in full color) of blue (B), green (G), and red (R) each emit light and each have characteristic spectrums, also similarly to the CRT.

The organic electroluminescence display devices can be classified into a bottom emission type and a top emission type according to an extraction direction of emitted light. The bottom emission type has merits in that, for example, a substrate may be manufactured with the same processes as that of a thin film transistor liquid crystal display device, formation of a cathode is easy, and sealing is also easy. A demerit thereof is a low aperture ratio because a pixel aperture is limited by the arrangement of the thin film transistor.

On the other hand, in the top emission type, the pixel is not affected by the arrangement of the thin film transistor, and the thin film transistor can be arranged on a pixel region, which provides a high aperture ratio. However, in this case, the pixel has a complicated cross-sectional structure, and it is necessary for a sealing can (sealing glass) to be transparent.

Both types of the organic electroluminescence display devices are constructed by incorporating a peripheral member such as a driving circuit into an organic electroluminescence panel (display panel) on which pixels including a plurality of organic electroluminescence elements are arranged in a matrix on an active substrate formed with a thin film transistor. Each of the organic electroluminescence elements includes one electrode provided on the active substrate for each unit color pixel including a plurality of sub-pixels to form a sub-pixel aperture, an organic electroluminescence layer formed on the one electrode, and another electrode formed to cover the organic electroluminescence layer.

In a mass production process, a vapor deposition method is used for forming the organic electroluminescence layer on the sub-pixel aperture. JP 2003-297562 A discloses a vapor deposition method in which an organic electroluminescence layer is formed on an organic electroluminescence panel by using a mask.

The organic electroluminescence layer of the organic electroluminescence panel included in the organic electroluminescence display device is formed by depositing on a large glass (mother glass) on which a large number of regions for organic electroluminescence panel formation are arranged, through a mask having an aperture pattern corresponding to a sub-pixel aperture of each organic electroluminescence panel. The vapor deposition using a mask causes a positional deviation in film formation (film formation deviation) due to a thermal expansion of the mask, with the result that the chromaticity fluctuation and the luminance fluctuation occur. In JP 2003-297562 A, a mask smaller in size than the mother glass is prepared and vapor deposition is performed by relatively moving the mother glass with respect to the mask, whereby the positional deviation in the film formation due to a thermal expansion is suppressed.

### SUMMARY OF THE INVENTION

However, in JP 2003-297562, analysis of how a film formation deviation occurs is not described. Further, there is no disclosure on measures against the film formation deviation generated at a time of manufacturing.

An object of the present invention is to optimize a film formation deviation of an organic electroluminescence layer to ensure white color uniformity.

According to the present invention, there is provided an organic electroluminescence display device including a display panel on which pixels including a plurality of organic electroluminescence elements are arranged in a matrix on an active substrate, in which each of the plurality of organic electroluminescence elements includes: one electrode provided on the active substrate for each unit color pixel including a plurality of sub-pixels to form a sub-pixel aperture; an organic electroluminescence layer formed on the one electrode; and another electrode formed to cover the organic electroluminescence layer, and an emission color of the organic electroluminescence layer formed on the sub-pixel aperture is any one of red, green, or blue. The organic electroluminescence layers for the red, the green, and the blue are formed on the sub-pixel aperture corresponding to the red, the sub-pixel aperture corresponding to the green, and the sub-pixel aperture corresponding to the blue, to form the unit color pixel. In the organic electroluminescence display device, a center of the sub-pixel aperture located at an arbitrary position on the display panel corresponds to a center of the organic electroluminescence layer formed thereon, and a center deviation of a film formation of the organic electroluminescence layer on the sub-pixel aperture corresponding to the green is made smaller than the center deviation of the film formation of the organic electroluminescence layer on the sub-pixel aperture corresponding to the red and the center deviation of the film formation of the organic electroluminescence layer on the sub-pixel aperture corresponding to the blue.

Further, according to an aspect of the present invention, when the center deviations of the film formation of the organic electroluminescence layers in an arrangement direction of the sub-pixel aperture corresponding to the red, the sub-pixel aperture corresponding to the green, and the sub-pixel aperture corresponding to the blue are denoted by LER(X), LEG(X), and LEB(X), and the center deviations in the film formation of the organic electroluminescence layers in a direction perpendicular to the arrangement direction are denoted by LER(Y), LEG(Y), and LEB(Y), any one of the following formulae may be satisfied:

LEG(X)≦LEB(X);

LEG(X)≦LER(X);

LEG(Y)≦LEB(Y); and

LEG(Y)≦LER(Y).

Further, according to another aspect of the present invention, any one of the following formulae may be satisfied:

LEG(X)≦LER(X)≦LEB(X); and

LEG(Y)≦LER(Y)≦LEB(Y).

Further, according to still another aspect of the present invention, the organic electroluminescence display device may be a top-emission organic electroluminescence display device in which the one electrode includes a reflective electrode and the another electrode includes a transparent electrode.

Further, according to still another aspect of the present invention, the organic electroluminescence display device may be a bottom-emission organic electroluminescence display device in which the one electrode includes a transparent electrode and the another electrode includes a reflective electrode.

According to the present invention, precision of the organic electroluminescence layer formed on the sub-pixel aperture corresponding to the green light can be improved and a high quality image display in which white color uniformity is ensured can be obtained. In addition, a complete examination is performed only on a vapor deposition mask of green color and examinations for masks of the remaining two colors can be simplified, whereby manufacturing cost can be reduced.

### BRIEF DESCRIPTION OF THE DRAWINGS

In the accompanying drawings:

FIG. 1 is a schematic diagram for explaining definition of a film formation deviation;

FIG. 2 is a chart for explaining a relationship between ΔCIE and a deviation amount in the film formation of an organic electroluminescence layer in each case of three color pixels, red, green, and blue;

FIG. 3 is a setting diagram of the deviation amounts in the film formation of the organic electroluminescence layers according to an embodiment of the present invention;

FIG. 4 is a plan view for explaining an organic electroluminescence display device according to the embodiment of the present invention; and

FIG. 5 is a plan view for explaining a related organic electroluminescence display device shown for comparison.

### DETAILED DESCRIPTION OF THE INVENTION

Hereinafter, a detailed description is made on an embodiment of the present invention. First, definition of a “film formation deviation” is described with reference to FIG. 1. In an organic electroluminescence element, a sub-pixel aperture 1 (1B, 1G, 1R) is formed on an active substrate for each unit color pixel including a plurality of sub-pixels. An organic electroluminescence layer 2 (2B, 2G, 2R) is deposited on the sub-pixel aperture 1 (1B, 1G, 1R). The three adjacent sub-pixel apertures 1B, 1G, and 1R correspond to three colors of blue, green, and red, and the three colors are used to enable full-color display. In FIG. 1, X denotes a row direction of matrix (normally, scan line direction) and Y denotes a column direction of matrix (normally, data line direction).

For the sub-pixel aperture 1 (1B, 1G, 1R), the line A-A′ is a central line in the Y direction and the line B-B′ is a central line in the X direction. An intersection P1 of the lines A-A′ and B-B′ is a center of the sub-pixel aperture 1 (1B, 1G, 1R). Also, for the organic electroluminescence layer 2 (2B, 2G, 2R) formed through deposition, the line C-C′ is a central line in the Y direction and the line D-D′ is a central line in the X direction. An intersection P2 of the lines C-C′ and D-D′ is a center of the organic electroluminescence layer 2 (2B, 2G, 2R). The film formation deviation of the organic electroluminescence layer is indicated by a distance (LE(X): LEB(X), LEG(X), LER(X), LE(Y): LEB(Y), LEG(Y), LER(Y)) extending from the center of the sub-pixel aperture 1, that is, P1, to the intersection P2 of the organic electroluminescence layer 2.

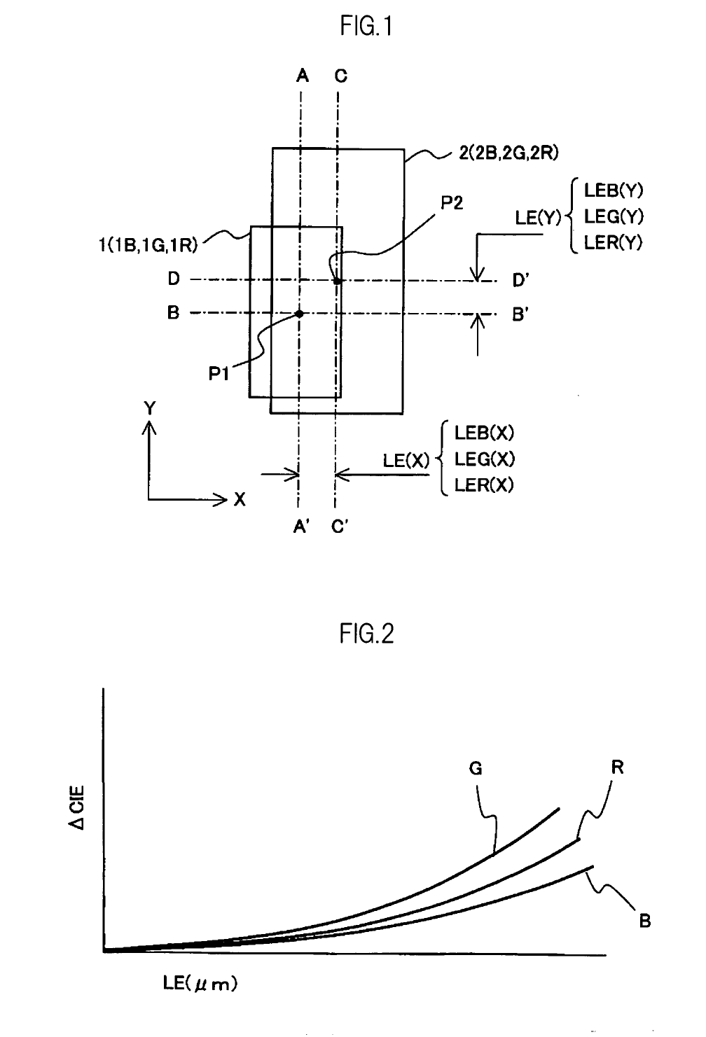

FIG. 2 is a chart for explaining a relationship between ΔCIE and a deviation amount in the film formation of an organic electroluminescence layer in each case of three color pixels, red, green, and blue. The abscissa axis shows the deviation amount in the film formation (μm) of an organic electroluminescence layer and the ordinate axis shows the difference (ΔCIE) in CIE XYZ color space between a point of a color of an observed light emitted by a white signal and a white point (reference white). The inventors of the present invention quantify white unevenness as a variation (difference) of a chromaticity value at a time of optimizing the design of an organic electroluminescence element, and evolve the relationship between the deviation amount LE in the film formation of each of the pixels and the ΔCIE. It is understood from FIG. 2 that the deviation amount LE in the film formation of the green (G) pixel has greater influence on the ΔCIE, which is an index value of white unevenness, compared with those of the blue (B) pixel and the red (R) pixel. In the embodiment of the present invention, the deviation amount LE in the film formation of each of the pixels is optimized.

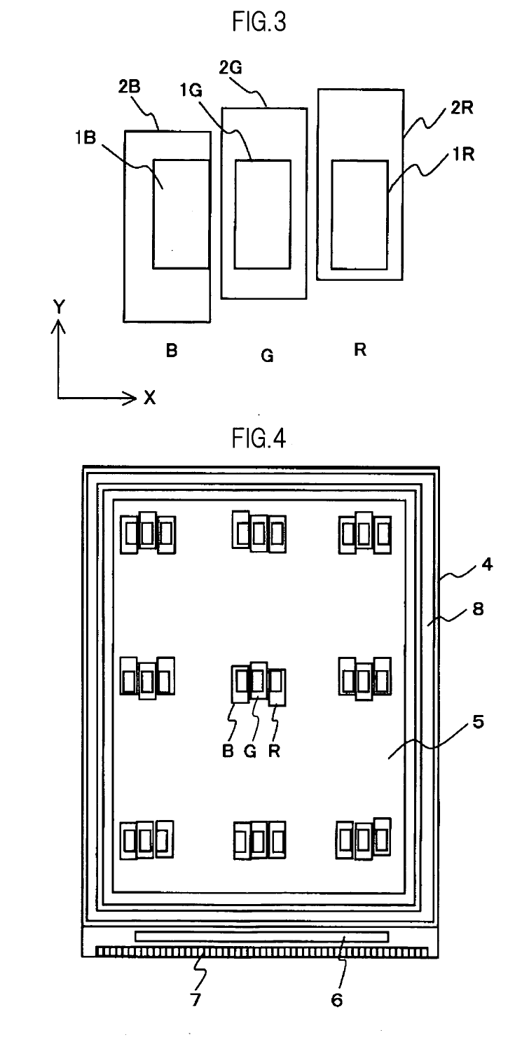

FIG. 3 is a setting diagram of the deviation amount in the film formation of the organic electroluminescence layer according to the embodiment of the present invention. In FIG. 3, a center deviation of the film formation of each of the organic electroluminescence layers 2R, 2G, and 2B in an arrangement direction (X direction) of the sub-pixel apertures 1R, 1G, and 1B of the three colors, red (R), green (G), and blue (B) is denoted by LER(X), LEG(X), and LEB(X), respectively. The center deviation of the film formation of each of the organic electroluminescence layers 2R, 2G, and 2B in a direction (Y direction) perpendicular to the arrangement direction (X direction) is denoted by LER(Y), LEG(Y), and LEB(Y), respectively. In this case, it is assumed that any one of the following formulae is satisfied:

LEG(X)≦LEB(X) (1);

LEG(X)≦LER(X) (2);

LEG(Y)≦LEB(Y) (3); and

LEG(Y)≦LER(Y) (4).

This can suppress the film formation deviation of the green pixel, which has the greatest influence on the ΔCIE, thereby improving a white color uniformity.

Moreover, in this embodiment, it may be assumed that one of the following formulae is further satisfied:

LEG(X)≦LER(X)≦LEB(X) (5); and

LEG(Y)≦LER(Y)≦LEB(Y) (6).

This can suppress more the film formation deviation of a pixel with a color, which has a greater influence on the ΔCIE, thereby further improving the white color uniformity.

FIG. 4 is a plan view for explaining the organic electroluminescence display device according to the embodiment of the present invention. The organic electroluminescence display device includes a display region 5 of an organic electroluminescence panel 4 (display panel) which is formed with an organic electroluminescence element on an active substrate provided with a thin film transistor. A driving circuit chip 6 is mounted on a lower short side of the organic electroluminescence panel 4, and a terminal portion 7 to be connected to an external device (host) is provided to an edge of the organic electroluminescence panel 4. Note that a sealing glass (not shown) is fixed with a seal 8. As shown in FIG. 4, the organic electroluminescence layer having the sub-pixels of the three colors, red (R), green (G), and blue (B) has less film formation deviation in the entire area of the display region 5.

With the organic electroluminescence display device according to the embodiment of the present invention, a high quality image display in which a white color uniformity is ensured can be obtained. Further, a complete examination is performed only on a vapor deposition mask of green color and examinations for masks of the remaining two colors can be simplified, whereby manufacturing cost can be reduced.

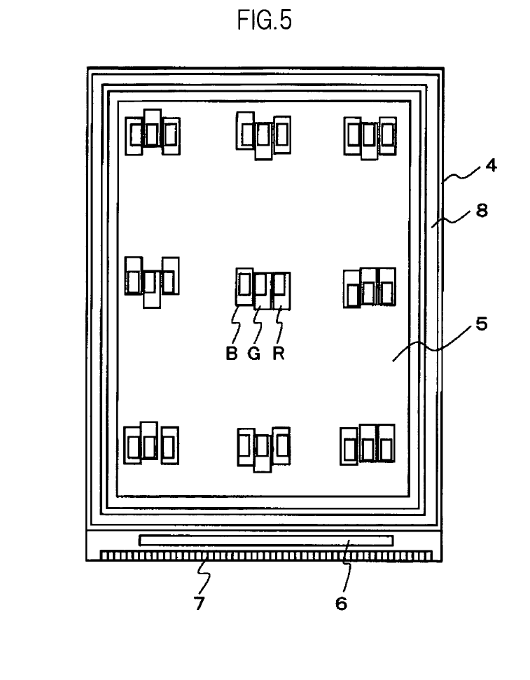

FIG. 5 is a plan view for explaining a related organic electroluminescence display device, which is shown for comparison. The same reference numerals denoted in FIG. 4 correspond to the same functional portions. As shown in FIG. 5, the organic electroluminescence layer having the sub-pixels of the three colors, red (R), green (G), and blue (B) has variation of the film formation deviations as a whole. Particularly in the green (G) sub-pixel, film formation deviations are large. In this organic electroluminescence panel, the following formulae are satisfied:

LEG(X)≧LEB(X) (1′);

LEG(X)≧LER(X) (2′);

LEG(Y)≧LEB(Y) (3′); and

LEG(Y)≧LER(Y) (4′).

Therefore, it is difficult to ensure the white color uniformity.

While there have been described what are at present considered to be certain embodiment of the invention, it will be understood that various modifications may be made thereto, and it is intended that the appended claims cover all such modifications as fall within the true spirit and scope of the invention.

1. An organic electroluminescence display device including a display panel on which pixels including a plurality of organic electroluminescence elements are arranged in a matrix on an active substrate, wherein:
each of the plurality of organic electroluminescence elements comprises:
one electrode provided on the active substrate for each unit color pixel including a plurality of sub-pixels to form a sub-pixel aperture;
an organic electroluminescence layer formed on the one electrode; and
another electrode formed to cover the organic electroluminescence layer;
an emission color of the organic electroluminescence layer formed on the sub-pixel aperture is any one of red, green, or blue; and
a center of the sub-pixel aperture located at an arbitrary position on the display panel corresponds to a center of the organic electroluminescence layer formed thereon, and a center deviation of a film formation of the organic electroluminescence layer on the sub-pixel aperture corresponding to the green is made smaller than the center deviation of the film formation of the organic electroluminescence layer on the sub-pixel aperture corresponding to the red and the center deviation of the film formation of the organic electroluminescence layer on the sub-pixel aperture corresponding to the blue.

2. An organic electroluminescence display device according to claim 1, wherein when the center deviations of the film formation of the organic electroluminescence layers in an arrangement direction of the sub-pixel aperture corresponding to the red, the sub-pixel aperture corresponding to the green, and the sub-pixel aperture corresponding to the blue are denoted by LER(X), LEG(X), and LEB(X), and the center deviations in the film formation of the organic electroluminescence layers in a direction perpendicular to the arrangement direction are denoted by LER(Y), LEG(Y), and LEB(Y), any one of the following formulae is satisfied:
LEG(X)≦LEB(X);
LEG(X)≦LER(X);
LEG(Y)≦LEB(Y); and
LEG(Y)≦LER(Y).

3. An organic electroluminescence display device according to claim 1, wherein when the center deviations in the film formation of the organic electroluminescence layers in an arrangement direction of the sub-pixel aperture corresponding to the red, the sub-pixel aperture corresponding to the green, and the sub-pixel aperture corresponding to the blue are denoted by LER(X), LEG(X), and LEB(X), and the center deviations in the film formation of the organic electroluminescence layers in a direction perpendicular to the arrangement direction are denoted by LER(Y), LEG(Y), and LEB(Y), any one of the following formulae is satisfied:
LEG(X)≦LER(X)≦LEB(X); and
LEG(Y)≦LER(Y)≦LEB(Y).

4. An organic electroluminescence display device according to claim 1, wherein the one electrode comprises a reflective electrode and the another electrode comprises a transparent electrode.

5. An organic electroluminescence display device according to claim 1, wherein the one electrode comprises a transparent electrode and the another electrode comprises a reflective electrode.

6. An organic electroluminescence display device according to claim 2, wherein the one electrode comprises a reflective electrode and the another electrode comprises a transparent electrode.

7. An organic electroluminescence display device according to claim 3, wherein the one electrode comprises a reflective electrode and the another electrode comprises a transparent electrode.

8. An organic electroluminescence display device according to claim 2, wherein the one electrode comprises a transparent electrode and the another electrode comprises a reflective electrode.

9. An organic electroluminescence display device according to claim 3, wherein the one electrode comprises a transparent electrode and the another electrode comprises a reflective electrode.
